(19) United States
(12) Patent Application Publication
(10) Pub. No.: US 2024/0021364 A1
(43) Pub. Date: Jan. 18, 2024

(54) ELECTRONIC COMPONENT AND METHOD FOR MANUFACTURING ELECTRONIC COMPONENT

(71) Applicant: Murata Manufacturing Co., Ltd., Kyoto-fu (JP)

(72) Inventor: Keisuke KUNIMORI, Nagaokakyo-shi (JP)

(73) Assignee: Murata Manufacturing Co., Ltd., Kyoto-fu (JP)

(21) Appl. No.: 18/348,030

(22) Filed: Jul. 6, 2023

(30) Foreign Application Priority Data
Jul. 13, 2022 (JP) 2022-112747

(51) Int. Cl. H01F 41/04; H01F 17/00; H01F 27/32

(52) U.S. Cl. CPC H01F 41/041; H01F 17/0013; H01F 27/324; H01F 2017/002; H01F 2017/0073

(57) ABSTRACT

An electronic component capable of increasing a ratio of a conductor to a thickness in an interlayer direction. An electronic component includes a first circuit pattern and a second circuit pattern stacked in this order from a lower side to an upper side in an interlayer direction; and an insulator disposed between the first circuit pattern and the second circuit pattern. In the second circuit pattern, an end portion on the lower side in the interlayer direction has a shape in which a width, which is a dimension perpendicular to the interlayer direction, narrows as the width is positioned on the lower side in the interlayer direction in sectional view of a section including the interlayer direction.

### CROSS-REFERENCE TO RELATED APPLICATION

This application claims benefit of priority to Japanese Patent Application No. 2022-112747, filed Jul. 13, 2022, the entire content of which is incorporated herein by reference.

### BACKGROUND

### Technical Field

The present disclosure relates to an electronic component and a method for manufacturing an electronic component.

### Background Art

Conventionally, there has been known a laminated electronic component including a laminated body in which an insulator layer and a conductor layer are laminated, the laminate body including a via that electrically connects a lower conductor layer and an upper conductor layer. Japanese Patent No. 6424453 and Japanese Patent Application Laid-Open No. 2020-194976 disclose a method for manufacturing such a laminated electronic component.

The manufacturing method disclosed in Japanese Patent No. 6424453 is as follows.

First, a conductor pattern made of copper foil or the like is formed on the entire surface of one surface of each of a first insulating substrate and a third insulating substrate made of thermoplastic resin. Next, a through hole is formed at a predetermined position of the second insulating substrate of the thermoplastic resin by laser processing, etching, or the like, and the through hole is filled with a conductive paste. Then, the first insulating substrate with the conductor pattern facing downward is defined as the uppermost layer, and the second insulating substrate and the third insulating substrate with the conductor pattern facing upward are stacked in this order. Then, the first insulating substrate, the second insulating substrate, and the third insulating substrate are heated and pressed to be integrated. During this heat-pressing, the conductive paste of the through hole is cured to form a via.

The manufacturing method disclosed in Japanese Patent Application Laid-Open No. 2020-194976 is as follows.

First, a groove is formed on a surface of a first insulating layer by photolithography. Next, a conductive paste is applied into the groove to form a coil conductor layer in the groove. Next, an insulating paste is applied onto the first insulating layer and the coil conductor layer by screen printing to form a second insulating layer, and a via conductor layer is formed on the second insulating layer. Then, a laminated body is formed by repeating these processes a plurality of times.

### SUMMARY

However, the conventional manufacturing method has the following problems.

The laminated body obtained by the manufacturing method of Japanese Patent No. 6424453 has a so-called sandwich structure in which a surface of the first insulating substrate on which the conductor pattern is formed and a surface of the third insulating substrate on which the conductor pattern is formed face each other with the second insulating substrate interposed therebetween. For this reason, in the manufacturing method of Japanese Patent No. 6424453, although the interval between two conductor patterns facing each other can be narrowed, in a case where the number of stacked layers is further increased, the conductor patterns are stacked with the insulating substrate interposed therebetween, so that the interval between the conductor patterns with the insulating substrate interposed therebetween cannot be narrowed. Therefore, the ratio of the conductor pattern to the thickness of the electronic component in the interlayer direction cannot be increased.

In the manufacturing method of Japanese Patent Application Laid-Open No. 2020-194976, when the coil conductor layer formed on the first insulating layer protrudes from the groove, if the thickness of the second insulating layer stacked on the first insulating layer is thin, the second insulating layer swells at the portion of the coil conductor layer, so that the second insulating layer has a wavy shape in sectional view including the interlayer direction, which hinders formation of another layer on the second insulating layer. Therefore, it is necessary to make the second insulating layer thick enough to absorb the protrusion of the coil conductor layer formed on the first insulating layer, and there is a limit to make the second insulating layer thin, so that the ratio of the coil conductor layer to the thickness of the electronic component in the interlayer direction cannot be increased.

Accordingly, the present disclosure provides an electronic component capable of increasing a ratio of a conductor to a thickness in an interlayer direction.

One aspect of the present disclosure includes a first circuit pattern and a second circuit pattern stacked in this order from a lower side to an upper side in an interlayer direction; and an insulator disposed between the first circuit pattern and the second circuit pattern, in which in the second circuit pattern, an end portion on the lower side in the interlayer direction has a shape in which a width, which is a dimension perpendicular to the interlayer direction, narrows as it is positioned on the lower side in the interlayer direction in sectional view of a section including the interlayer direction.

Another aspect of the present disclosure is a method for manufacturing an electronic component, the method including a first step of forming a first circuit pattern on a plane; a second step of forming a photosensitive insulating material so as to cover the first circuit pattern; a third step of forming a second circuit pattern trench by exposure and development of a surface of the insulating material; and a fourth step of filling the second circuit pattern trench with a conductive material to form a second circuit pattern, in which in the third step, the second circuit pattern trench having a bottom portion in which a width, which is a dimension perpendicular to an interlayer direction, narrows as a depth increases along the interlayer direction is formed, the interlayer direction being a direction in which the first circuit pattern and the second circuit pattern are stacked.

According to the present disclosure, the ratio of the conductor to the thickness in the interlayer direction can be increased.

### BRIEF DESCRIPTION OF THE DRAWINGS

FIG. 1 is a schematic view illustrating an internal structure of a coil component according to a first embodiment of the present disclosure;

FIG. 2 is an enlarged view illustrating each of a second circuit pattern and a via in sectional view of a section including an interlayer direction of a laminated body;

FIG. 3 is a view illustrating an example of a manufacturing process of the coil component;

FIG. 4 is a view illustrating processing steps of exposure development processing;

FIG. 5 is a view illustrating scattering, diffraction, and reflection of light inside an insulating material;

FIG. 6 is a view illustrating a process of forming a trench having a curved portion;

FIG. 7 is a view illustrating a relationship between a development time and a shape of a second circuit pattern trench;

FIG. 8 is a view illustrating a relationship between a focal position of exposure light and a shape of a trench;

FIG. 9 is a schematic view of an internal structure of a coil component according to a second embodiment of the present disclosure;

FIG. 10 is a diagram illustrating a wiring topology of a coil body in the coil component;

FIG. 11 is a view illustrating an example of a manufacturing process of the coil component; and

FIG. 12 is a schematic view illustrating a configuration of a laminated body according to another embodiment of the present disclosure.

### DETAILED DESCRIPTION

Hereinafter, embodiments of the present disclosure will be described with reference to the drawings.

In the present embodiment, a coil component will be described as an example of a laminated electronic component. The drawings may include schematic views at a part thereof.

In addition, dimensions and ratios in the schematic views may be different from actual numerical values.

### First Embodiment

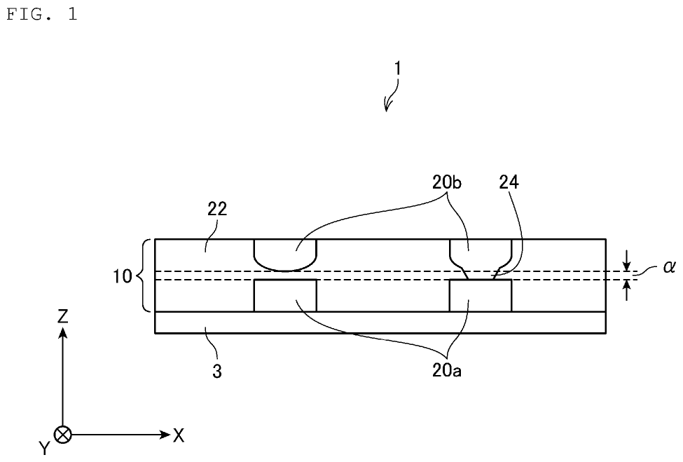

FIG. 1 is a schematic view of an internal structure of a coil component 1 according to the present embodiment.

The coil component 1 includes a first circuit pattern 20a and a second circuit pattern 20b stacked in one direction on a flat surface of a support plate 3 made of an insulating material, and an insulator 22 made of an insulating material disposed between the first circuit pattern 20a and the second circuit pattern 20b. The first circuit pattern 20a, the second circuit pattern 20b, and the insulator 22 constitute a laminated body 10. A pair of external electrodes (not shown) is provided on the surface of the laminated body 10.

Here, a direction in which the first circuit pattern 20a and the second circuit pattern 20b are stacked is defined as an interlayer direction (also referred to as an interlayer direction), and is denoted by a reference numeral Z. A plane orthogonal to the interlayer direction Z is defined as an XY plane. The X direction of the XY plane corresponds to the left-right direction of the drawing, and the Y direction corresponds to the depth direction of the drawing.

In the present specification, the terms “upper”, “lower”, “left”, and “right” used for each of the interlayer direction Z, the X direction, and the Y direction are used for convenience based on the drawings in order to distinguish the relative directions, and do not correspond to the vertical direction and the horizontal direction indicating the absolute direction, and the direction based on the posture of the electronic component in the mounting state or the use state.

Hereinafter, a direction of the support plate 3 along the interlayer direction is referred to as a “lower side”, and a direction facing the support plate 3 along the interlayer direction is referred to as an “upper side”.

The first circuit pattern 20a and the second circuit pattern 20b extend along the XY plane, and a part of the first circuit pattern 20a and a part of the second circuit pattern 20b are electrically connected to each other by a via 24 to form a coil body having a winding shape.

The coil component 1 may include the laminated body 10 in a part thereof. That is, in sectional view of a section including the interlayer direction Z, the coil component 1 does not need to have the structure of the laminated body 10 illustrated in FIG. 1 in the entire section, and may have the structure of the laminated body 10 in a part of the section.

The insulator 22 is mainly made of an insulating material and is a main component of an element body of the coil component 1. That is, the coil component 1 has a structure in which the above-described coil body is embedded inside the insulating element body formed of the insulator 22.

In the present embodiment, the insulating material constituting the insulator 22 is, for example, a sintered body of glass. The glass is formed, for example, by firing a glass paste obtained by mixing a glass powder with a photosensitive insulating resin and also containing a filler material mainly composed of aluminum oxide (Al₂O₃) in order to secure the strength of the element body. Since the insulator 22 made of such an insulating material is also a nonmagnetic body, the coil component 1 has a high quality factor (Q value) and a suppressed magnetic loss, and is suitable for various circuits for a high frequency signal in a gigahertz band, a wireless communication circuit, and the like. However, the insulating material constituting the insulator 22 is not limited to glass or a nonmagnetic material, and may be obtained by curing another sintered body such as alumina or ferrite, a nonmagnetic resin, or a magnetic powder-containing resin.

Similarly to the insulator 22, the support plate 3 is a layer mainly made of an insulating material, and is made of the same insulating material. The support plate 3 and the insulator 22 are integrated as a region of the insulating material. Note that the support plate 3 only needs to be a layer in which the first circuit pattern 20a is formed on the main surface thereof, and does not actually need to have a support function or strength for securing the support function. Further, the support plate 3 may have a multilayer structure, and a part of the multilayer may be colored to have a marker function.

The first circuit pattern 20a, the second circuit pattern 20b, and the via 24 are formed of a conductive material.

In the present embodiment, the conductive material is, for example, a metal such as silver (Ag), copper (Cu), gold (Au), aluminum (Al), or an alloy containing these as a main component. The metal may be obtained by sintering a conductive paste obtained by mixing a metal powder with a resin, or may be obtained by forming the metal by a thin film method.

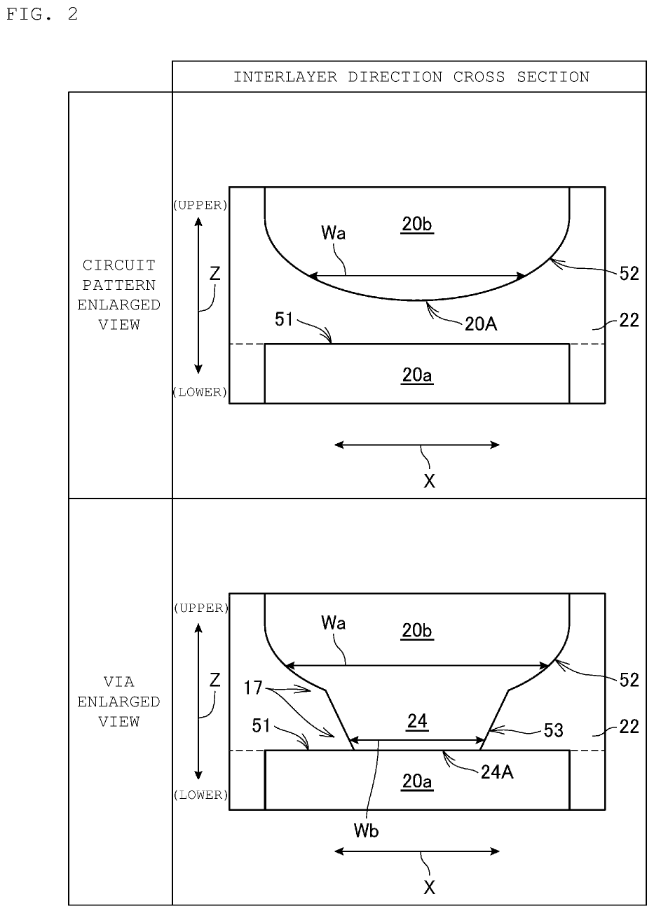

FIG. 2 is an enlarged view illustrating each of the second circuit pattern 20b and the via 24 in sectional view of a section of including the interlayer direction Z of the laminated body 10. Hereinafter, a section including the interlayer direction Z is referred to as an “interlayer direction section”. The interlayer direction section is a section crossing the extending direction of the second circuit pattern 20b and passing through the center of the via 24. If the coil component 1 has a structure in which such a section cannot be acquired, a section of the second circuit pattern 20b and a section passing through the center of the via 24 may be acquired separately, and each may be taken as an interlayer direction section.

As illustrated in the drawing, the coil component 1 includes the first circuit pattern 20a and the second circuit pattern 20b laminated in this order from the lower side to the upper side in the interlayer direction Z, and the insulator 22 disposed between the first circuit pattern 20a and the second circuit pattern 20b. That is, the upper side in the interlayer direction Z is a direction from the first circuit pattern 20a toward the second circuit pattern 20b, and the lower side in the interlayer direction Z is a direction from the second circuit pattern 20b toward the first circuit pattern 20a.

As described above, the coil component 1 further includes the via 24 that electrically connects the first circuit pattern 20a and the second circuit pattern 20b. In the interlayer direction sectional view, curved portions 52 and 53 are included in the outer shapes of the second circuit pattern 20b and the via 24. These curved portions 52 and 53 are formed at end portions 20A and 24A of the second circuit pattern 20b and the via 24 on the lower side in the interlayer direction Z. Due to these curved portions 52 and 53, in each of the second circuit pattern 20b and the via 24, the end portion on the lower side in the interlayer direction has a shape in which the widths Wa and Wb in the X direction, which are dimensions perpendicular to the interlayer direction, become narrower as they are positioned on the lower side in the interlayer direction in sectional view of a section including the interlayer direction. The width Wa is a dimension perpendicular to the interlayer direction of the second circuit pattern 20b in the interlayer direction sectional view, and the width Wb is a dimension perpendicular to the interlayer direction of the via 24 in the interlayer direction sectional view.

That is, the end portion of the second circuit pattern 20b on the lower side in the interlayer direction Z has a curved surface shape, so that the close contact property with the insulator 22 that is relatively thin at the portion of the second circuit pattern 20b on the lower side can be improved, and the occurrence of peeling between the second circuit pattern 20b and the insulator 22 can be suppressed.

Further, a portion 51 which is an end portion of the first circuit pattern 20a on the upper side in the interlayer direction on the opposite side to the curved portion 52 in the interlayer direction Z is substantially linear in the X direction, and the via 24 is connected to the substantially linear portion 51. That is, the end portions of the first circuit pattern 20a and the second circuit pattern 20b on the upper side in the interlayer direction Z have a flat surface shape, and thus, by increasing the sectional areas of the first circuit pattern 20a and the second circuit pattern 20b, the DC electric resistance can be reduced. In the present embodiment, as illustrated in FIG. 1, the end portion of the first circuit pattern 20a on the lower side in the interlayer direction Z also has a flat surface shape, and the DC electric resistance of the first circuit pattern 20a can be further reduced.

In the present embodiment, the maximum value of the width Wb of the via 24 is smaller than the maximum value of the width Wa of the second circuit pattern 20b, and a step shape is formed in the connection portion 17 between the second circuit pattern 20b and the via 24.

As described above, since the second circuit pattern 20b and the via 24 have a shape in which the widths Wa and Wb are narrowed in the interlayer direction Z, the ratio of the conductors (that is, the first circuit pattern 20a and the second circuit pattern 20b) to the thickness in the interlayer direction Z can be increased as described later as compared with a case where the widths Wa and Wb are substantially constant. In addition, since the second circuit pattern 20b and the via 24 have the shape described above, the insulating material of the insulator 22 enters the periphery of each of the end portion 20A of the second circuit pattern 20b and the end portion 24A of the via 24, and the close contact property between the layers in the laminated body 10 can be improved. In particular, since the connection portion 17 has a stepped shape, the close contact property can be further improved.

In the laminated body 10 of the present embodiment, the thickness of the insulator 22 in the interlayer direction Z below the second circuit pattern 20b is 1 μm or more and 5 μm or less (i.e., from 1 μm to 5 μm). In addition, in the interlayer direction sectional view, the width of the second circuit pattern 20b in the X direction is 10 μm or more and 30 μm or less (i.e., from 10 μm to 30 μm), and the thickness of the second circuit pattern 20b in the interlayer direction Z is 10 μm or more and 30 μm or less (i.e., from 10 μm to 30 μm). Further, as the overall dimension of the coil component 1, the dimension in the longitudinal direction is 1.0 mm or less, and particularly preferably 0.4 mm or less. The dimension in the interlayer direction is 0.5 mm or less, and particularly preferably 0.2 mm or less. Furthermore, the dimension in the direction orthogonal to both the longitudinal direction and the interlayer direction is 0.5 mm or less, and particularly preferably 0.2 mm or less.

Next, a method for manufacturing the coil component 1 according to the present embodiment will be described in detail.

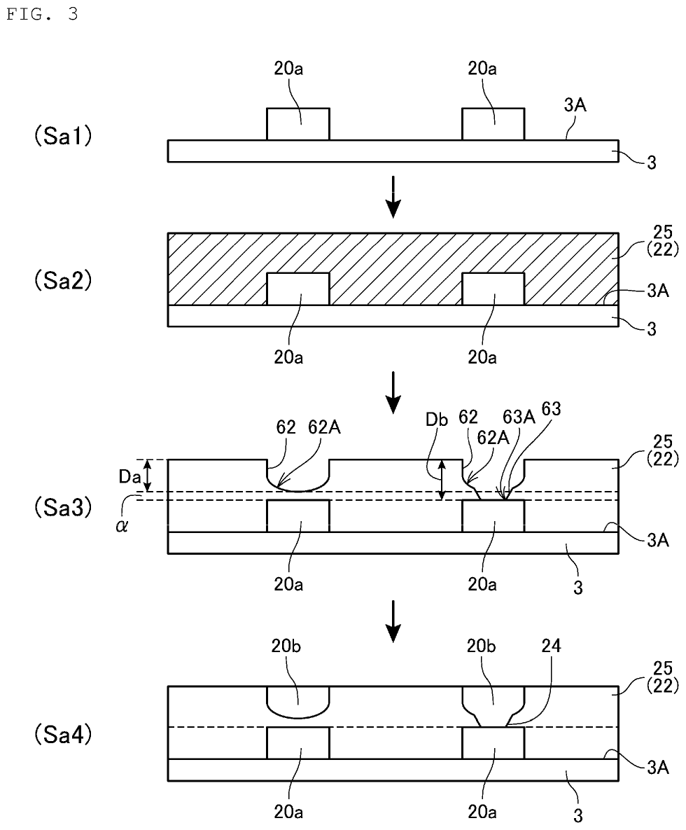

FIG. 3 is a view illustrating an example of a manufacturing process of the coil component 1. In each drawing illustrating a section, hatching does not clearly indicate the section, but indicates that the photosensitive glass paste (insulating material) is in an uncured state.

First, the first circuit pattern 20a as a first layer is formed on a flat surface, that is, on the upper surface of the support plate 3 by printing with a conductive paste and drying the conductive paste (step Sa1). Step Sa1 corresponds to a first step of forming a first circuit pattern on a flat surface in the present disclosure.

Next, an insulating material 25 which is a photosensitive glass paste to be the insulator 22 is applied on an upper surface 3A of the support plate 3 so as to cover the first circuit pattern 20a, and then the insulating material 25 is dried (step Sa2). Step Sa2 corresponds to a second step of forming a photosensitive insulating material so as to cover the first circuit pattern in the present disclosure. By steps Sa1 and Sa2, the first circuit pattern 20a embedded in the insulator 22 is formed.

Next, processing of forming the second circuit pattern 20b and the via 24 is performed.

Specifically, first, second circuit pattern trenches 62 and a via trench 63 are formed by performing exposure development processing to be described later on the surface of the insulating material 25 (step Sa3). Step Sa3 corresponds to a third step of forming a second circuit pattern trench by exposure and development of the surface of the insulating material in the present disclosure.

The second circuit pattern trench 62 is a groove formed at the depth Da not reaching the first circuit pattern 20a, that is, the depth Da at which the insulator 22 having a predetermined thickness can be obtained between the second circuit pattern trench 62 and the first circuit pattern 20a.

On the other hand, the via trench 63 is a through hole formed at the bottom portion of a part of the second circuit pattern trench 62, penetrating the insulator 22, and reaching the lower first circuit pattern 20a. Hereinafter, the predetermined thickness of the insulator 22 below the second circuit pattern 20b is referred to as an “interlayer distance α”. The entire depth Db of the second circuit pattern trench 62 including the via trench 63 at the bottom portion is a sum of the depth Da of the second circuit pattern trench 62 and the interlayer distance α.

In addition, the second circuit pattern trench 62 and the via trench 63 formed in step Sa3 include curved portions 62A and 63A having shapes corresponding to the curved portions 52 and 53 in the interlayer direction sectional view at the bottom portions, respectively. That is, in step Sa3, which is the third step, the second circuit pattern trench 62 having the bottom portion in which the width Wa, which is the dimension perpendicular to the interlayer direction, narrows as the depth increases along the interlayer direction, which is the direction in which the first circuit pattern 20a and the second circuit pattern 20b are stacked.

As described above, in the exposure development processing in step Sa3, the second circuit pattern trench 62 and the via trench 63 having the different depths Da and Db and including the curved portions 62A and 63A are formed in the same processing step, and the processing step is simplified. Such exposure development processing will be described later.

Next, the second circuit pattern trench 62 and the via trench 63 are filled with a conductive paste by printing, and the conductive paste is dried (step Sa4). As a result, the second circuit pattern 20b and the via 24 are formed. Step Sa4 corresponds to a fourth step of forming a second circuit pattern by filling the second circuit pattern trench with a conductive material in the present disclosure.

Thereafter, the laminated body 10 is fired under predetermined conditions, and then subjected to barrel finishing to provide an external electrode on the surface of the laminated body 10, and the external electrode is plated with tin (Sn), nickel (Ni), or the like, thereby completing the laminated coil component 1. However, the external electrode may be formed inside the laminated body 10 (that is, the inside of the insulating material 25) simultaneously with the second circuit pattern 20b.

Note that screen printing or inkjet printing can be used for the printing in steps Sa1 to Sa4, and screen printing is used in the present embodiment.

According to the manufacturing method of the present embodiment, since the depth of the second circuit pattern trench 62 formed in the insulating material 25 can be accurately controlled using photolithography, the thickness of the insulating material 25 between the second circuit pattern 20b and the first circuit pattern 20a can be controlled to be thin, and the ratio of the first circuit pattern 20a and the second circuit pattern 20b, which are conductors, to the thickness (that is, the thickness of the laminated body 10 in the interlayer direction) in the interlayer direction as a whole of the insulating material 25 can be increased.

In addition, since the thickness of the insulator 22 below the second circuit pattern 20b, that is, the interlayer distance α is controlled by the depth Da of the second circuit pattern trench 62, a thin interlayer distance α of 1 μm or more and 5 μm or less (i.e., from 1 μm to 5 μm) can be realized without being limited in printing performance as compared with the configuration in which the insulator layer is formed on the conductor layer by screen printing as in Japanese Patent Application Laid-Open No. 2020-194976 described above. As a result, the ratio of the first circuit pattern 20a and the second circuit pattern 20b, which are conductors, to the thickness of the laminated body 10 in the interlayer direction Z can be increased, and the coil component 1 with higher performance can be obtained.

Next, the exposure development processing in step Sa3 will be described in detail.

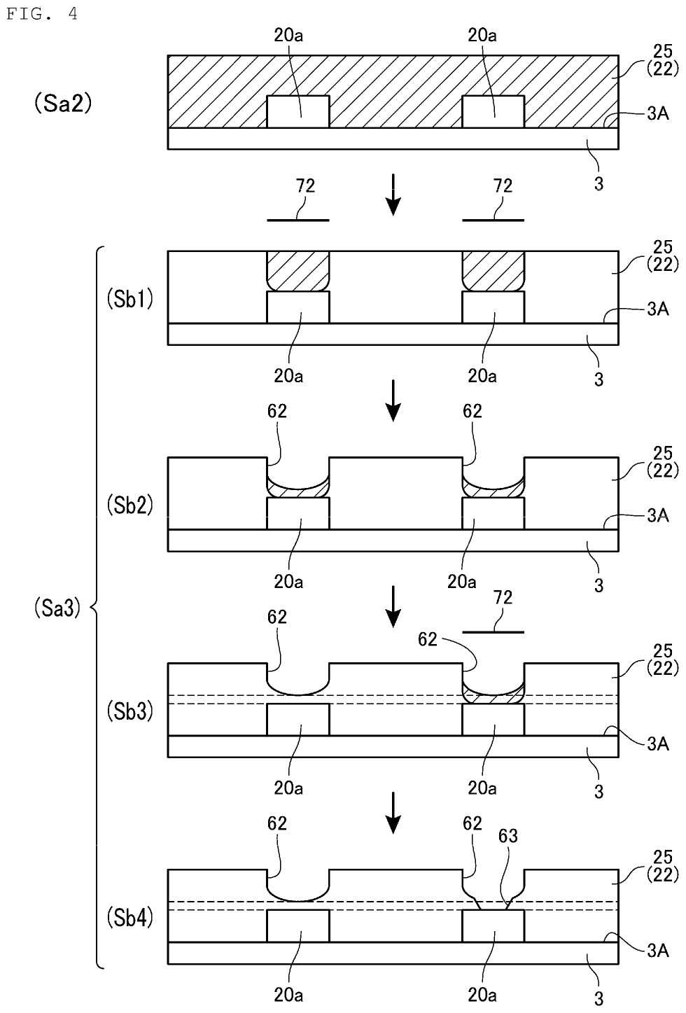

FIG. 4 is a view illustrating processing steps of the exposure development processing.

In the exposure development processing in step Sa3, which is the third step, after the second circuit pattern trench 62 is formed by exposure and development of the surface of the insulating material 25, the via trench 63 is formed on the bottom portion of at least a part of the second circuit pattern trench 62 by additional exposure and development with respect to the insulating material 25 at the bottom portion.

Specifically, first, first exposure is executed in a state in which photomasks 72 and 72 are arranged at positions separated upward in the interlayer direction Z by a predetermined distance from the surface of the uncured insulating material 25 formed by the printing in the above-described step Sa2 (step Sb1), and then the development is performed (step Sb2). The photosensitive insulating material 25 of the present embodiment is a negative material, and in the first exposure and development, the second circuit pattern trenches 62 having the depth Da (<Db) are formed immediately below the photomasks 72 and 72.

Next, second exposure is executed in a state where the photomask 72 is arranged at a position separated upward by a predetermined distance in the interlayer direction Z from the second circuit pattern trench 62 in which the via trench 63 is to be formed and the photomask 72 is not arranged in the other second circuit pattern trench 62 (step Sb3), and then development is performed (step Sb4).

By the second (that is, additional) exposure and development, the via trench 63 is formed at the bottom portion of the second circuit pattern trench 62 in which the via 24 is to be formed. On the other hand, in the second exposure in step Sb3, the bottom portion (for example, the bottom portion of the second circuit pattern trench 62 on the left side in the drawing) of the portion of the second circuit pattern trench 62 that is not the formation target of the via 24 is cured, so that the thickness of the insulating material 25 between the bottom portion of the second circuit pattern trench 62 and the first circuit pattern 20a is formed to a thickness corresponding to the interlayer distance α.

According to such exposure development processing, since the second circuit pattern trench 62 and the via trench 63 are formed, the second circuit pattern 20b and the via 24 can be simultaneously formed by executing the processing of filling both the second circuit pattern trench 62 and the via trench 63 with the conductive paste (FIG. 3: step Sa4).

In addition, since the layer of the insulator 22 is formed between the first circuit pattern 20a and the second circuit pattern 20b by forming the second circuit pattern trenches 62, a process of separately forming an insulator layer between the first circuit pattern 20a and the second circuit pattern 20b becomes unnecessary, and the processing steps can be simplified.

Meanwhile, in the present embodiment, the insulating material 25 contains a filler material having a refractive index larger than that of the main material, and when the second circuit pattern trench 62 and the via trench 63 are formed by exposure and development with respect to the insulating material 25, the above-described curved portions 62A and 63A are formed at the respective bottom portions.

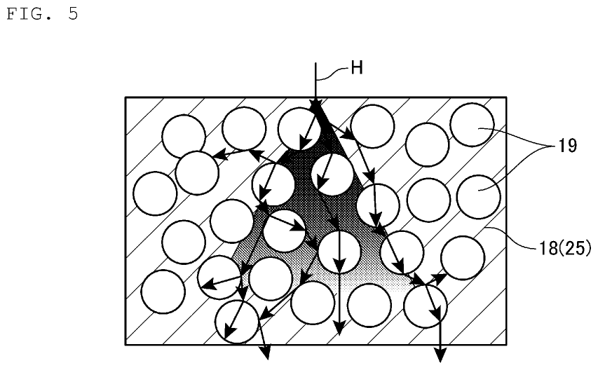

More specifically, as illustrated in FIG. 5, a glass paste 18 used as the insulating material 25 contains a filler material 19, and aluminum oxide is used for the filler material 19 in order to secure the strength of the element body. Since aluminum oxide has a refractive index higher than that of the insulating material 25 (more precisely, the insulating resin which is a main material of the insulating material 25), when the photosensitive insulating material 25 is exposed to form the second circuit pattern trench 62 and the via trench 63, scattering, diffraction, and reflection of light H used for exposure occur inside the insulating material 25 as illustrated in FIG. 5. The following processing can be realized by appropriately adjusting the scattering, diffraction, and reflection of the light H according to the content of aluminum oxide.

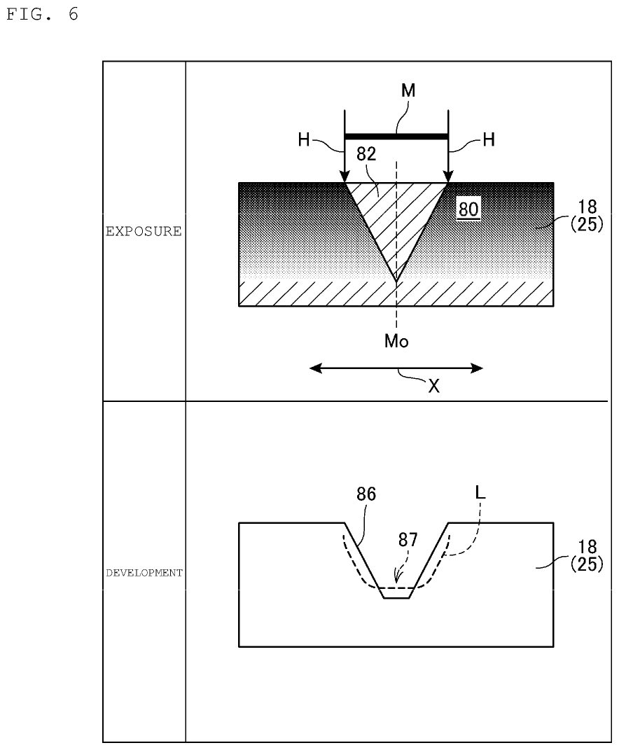

Specifically, as illustrated in FIG. 6, the content of aluminum oxide in the filler material 19 is adjusted such that exposure light H spreads in the X direction by scattering as the depth from the surface of the glass paste 18 increases, and enters also immediately below a photomask M at the time of exposure in which parallel light exposure light H is irradiated. In this case, in the interlayer direction sectional view, the shape of a cured area 80 to be photocured becomes a substantially tapered shape that enters toward the center Mo of the photomask M as the depth from the surface of the glass paste 18 increases, and an uncured area 82 immediately below the photomask M has a substantially V shape. Then, the uncured area 82 is removed by development to form a trench 86 having a substantially V shape. At the time of development, the development time is adjusted so that the deep portion (apex portion of the V shape) of the uncured area 82 is not dissolved. As a result, as indicated by a dotted line L, the surface of the trench 86 has a smooth curved shape, and the trench 86 including a curved portion 87 including a curve at the bottom portion is formed. The trench 86 corresponds to the second circuit pattern trench 62 and the via trench 63.

The above processing is not limited to the method of adjusting the content of aluminum oxide in the filler material 19. For example, by setting the size of the filler material to about several times (for example, 2 times or 3 times) the wavelength of the exposure light H, scattering, diffraction, and reflection can be remarkably generated, and the trench 86 including the curved portion 87 is easily formed. The filler material of the present embodiment has a size of 1 μm or 1 μm or less.

As the filler material that causes scattering, silicon dioxide (SiO₂) or silicon nitride (SiN) can be used in addition to aluminum oxide (Al₂O₃).

In addition to using the optical action of the filler material 19, the second circuit pattern trench 62 and the via trench 63 having the curved portions 62A and 63A can be formed by performing development time control and focal position control of the light H used for exposure.

The development time control is control for performing development with the development time in steps Sb2 and Sb4 being shorter than the break point BP in the exposure development processing of FIG. 4. The break point BP is a development time during which, in a state where the range from the surface of the insulating material to the lower first circuit pattern 20a is the uncured area 82, substantially the entire uncured area 82 is melted to form the trench 86 penetrating the lower first circuit pattern 20a. In step Sb2 and step Sb4, the thickness of the insulating material to the lower first circuit pattern 20a differs, so that the break point BP also differs.

That is, in the development time control, in step Sb2 of the exposure development processing (that is, step Sa3 which is the third step) illustrated in FIG. 4, the second circuit pattern trench 62 is developed in a development time shorter than the break point BP which is a development time during which the insulating material 25 at the formation portion penetrates the first circuit pattern 20a. In addition, in step Sb4, the via trench 63 is developed in a development time shorter than the break point BP which is a development time in which substantially the entire uncured area 82 of the insulating material 25 at the formation portion is melted.

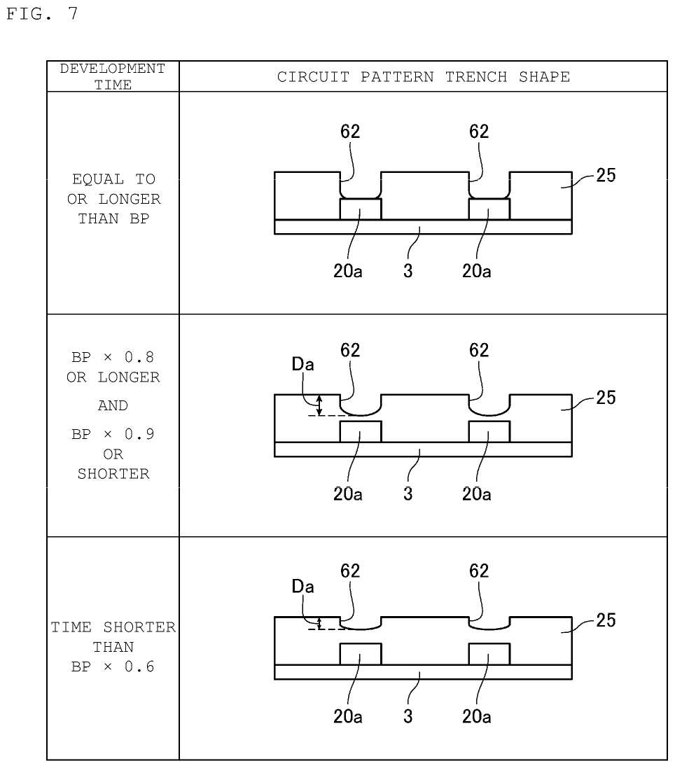

Hereinafter, the development time control will be described with reference to FIG. 7 by taking the development of the two second circuit pattern trench 62 in step Sb2 as an example. As illustrated in the drawing, when the development time is equal to or longer than the break point BP, the two second circuit pattern trenches 62 are through holes penetrating the lower first circuit pattern 20a, whereas when the development time is shorter than the break point BP, the two second circuit pattern trenches 62 are not through holes, and the uncured insulating material 25 remains between the two second circuit pattern trenches 62 and the lower first circuit pattern 20a.

The uncured insulating material 25 is photocured by re-exposure in step Sb3 to become a portion of the insulator 22 below the second circuit pattern 20b. Since there is a correlation between the development time and the depth Da such that the depth Da of the second circuit pattern trench 62 becomes shallower as the development time is shorter, the depth Da of the second circuit pattern trench 62 can be controlled by adjusting the development time, and the thickness of the insulator 22 under the second circuit pattern 20b can be set to a desired thickness (desired interlayer distance α).

In addition, when the development is stopped at the development time at which the second circuit pattern trench 62 reaches the depth Da not penetrating the lower first circuit pattern 20a, the shape of the bottom portion of the second circuit pattern trench 62 becomes a curved shape, whereby the curved portion 62A is formed at the bottom portion.

When the development time is shorter than the break point BP, the curvature of the curved portion 62A increases as the development time approaches the break point BP. However, in a case where the development time is set to be sufficiently longer than the break point BP, since all the uncured portions of the insulating material 25 are removed, the curvature depends on the cured shape (that is, the penetration degree of the exposure light) and is independent of the development time.

The focal position control is control for adjusting the focal position P of the light H used for exposure in each of steps Sb1 and Sb3 in the exposure development processing of FIG. 4.

Specifically, in the focal position control, in step Sb1 and step Sb3 of the exposure development processing (step Sa3 which is the third step) illustrated in FIG. 4, light used for exposure of the insulating material 25 is irradiated so as to be focused on the surface of the insulating material 25 or inside the insulating material 25 with respect to the surface.

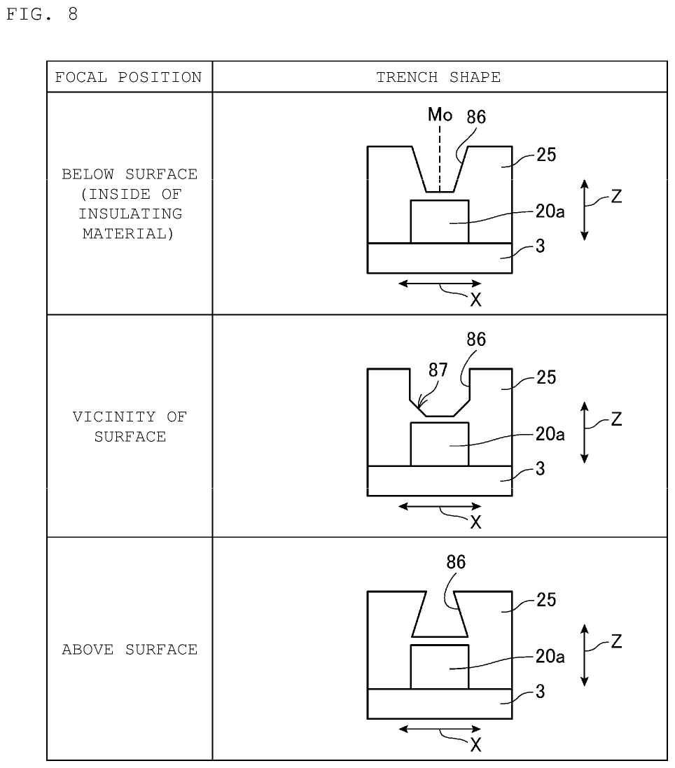

As illustrated in FIG. 8, in a case where the surface of the insulating material 25 is irradiated with the light H having passed through the photomask M through a condenser lens, when the focal position P of the condenser lens is located below (that is, the inside of the insulating material 25) the surface of the insulating material 25 in the interlayer direction Z, the illuminance inside the insulating material 25 is higher than that when light H of parallel light is irradiated. Therefore, the cured area 80 illustrated in FIG. 6 spreads to a region closer to the center Mo of the photomask M, and as a result, as illustrated in FIG. 8, the trench 86 in which the width in the X direction is narrowed as a whole is formed. In this case, it can also be said that not only the bottom portion of the trench 86 but also the entire trench 86 is the curved portion 87 (shape in which the width narrows toward the lower side in the interlayer direction Z).

When the focal position P of the condenser lens is located in the vicinity of the surface of the insulating material, a side surface 86S in the vicinity of the opening of the trench 86 is substantially vertical (substantially parallel to the interlayer direction Z) because the influence of scattering of the light H and the like in the vicinity of the surface is small. In addition, as the depth from the surface increases, the influence of scattering of the light H and the like increases, so that the curved portion 87 is formed at the bottom portion of the trench 86 as described with reference to FIG. 6.

In this manner, the trench 86 having the curved portion 87 can be formed by performing exposure in a state where the focal position P of the condenser lens is disposed in the vicinity of the surface of the insulating material and below the surface.

However, when the focal position P of the condenser lens is located above the surface of the insulating material 25, the illuminance of the light H is weakened as the depth from the surface increases, and the influence of scattering and the like is increased, so that the insulating material 25 is less likely to be cured at a position deeper from the surface than when the light H of parallel light is irradiated. As a result, as illustrated in FIG. 8, not only the trench 86 has a reverse tapered shape, but also the width of the opening is narrowed, so that it is difficult to fill the conductive paste.

Note that the trench 86 having the curved portion 87 may be formed by using any combination of any two or more of the filler material 19, development time control, and focal position control.

### Second Embodiment

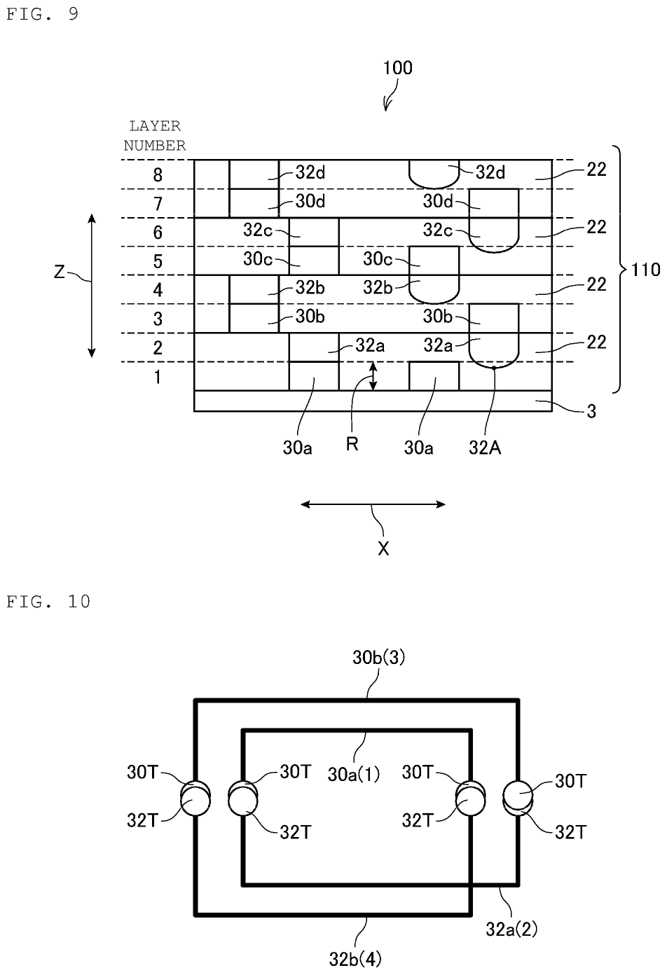

FIG. 9 is a schematic view of an internal structure of the coil component 100 according to the present embodiment. In the drawing, the members described in FIG. 1 are denoted by the same reference numerals, and the description thereof will be omitted.

As illustrated in the drawing, in a laminated body 110 included in the coil component 100 of the present embodiment, four first circuit patterns 30a, 30b, 30c, and 30d having the same configuration as the first circuit pattern 20a illustrated in the first embodiment and four second circuit patterns 32a, 32b, 32c, and 32d having the same configuration as the second circuit pattern 20b are alternately stacked on a support plate 3 in an interlayer direction sectional view. Hereinafter, the first circuit patterns 30a, 30b, 30c, and 30d are also collectively referred to as a first circuit pattern 30, and the second circuit patterns 32a, 32b, 32c, and 32d are also collectively referred to as a second circuit pattern 32.

In the laminated body 110, in the interlayer direction sectional view, an end portion 32A of the second circuit pattern 32a on the lower side in the interlayer direction Z is located on the lower side in the interlayer direction Z with respect to an end portion of the first circuit pattern 30a on the upper side in the interlayer direction Z below the end portion 32A.

The first circuit pattern 30c and the second circuit pattern 32c are configured similarly to that described above.

As a result, in the laminated body 110 of the coil component 100, the ratio of the first circuit pattern 30 and the second circuit pattern 32, which are conductors, to the thickness of the laminated body 110 in the interlayer direction Z can be further increased as compared with the laminated body 10 or a laminated body 11 (FIG. 12) to be described later in which a plurality of second circuit patterns 20b are configured in multiple layers.

In the laminated body 110, a part of each of the first circuit patterns 30 and a part of the adjacent second circuit pattern 32 are formed so as to be directly joined without interposing a via 24 in the interlayer direction sectional view to constitute a coil body.

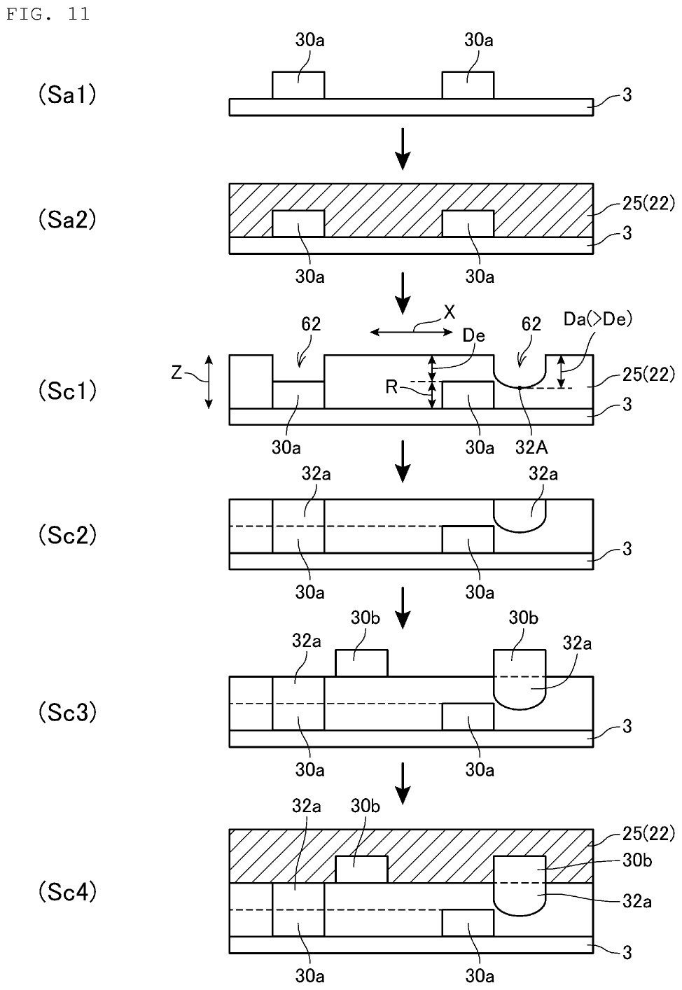

FIG. 10 is a diagram illustrating a wiring topology of the coil body in the coil component 100. The “wiring topology” refers to schematically representing a connection relationship between each of the first circuit patterns 30 and each of the second circuit patterns 32. Furthermore, in the drawing, parentheses attached to the respective reference numerals of the first circuit pattern 30 and the second circuit pattern 32 indicate layer numbers of layers in which the first circuit pattern 30 or the second circuit pattern 32 is formed (see FIG. 9). FIG. 10 illustrates a wiring topology formed by the first circuit patterns 30 and the second circuit patterns 32 from the first layer to the fourth layer. The wiring topology of the first circuit patterns 30 and the second circuit patterns 32 from the fifth layer to the eighth layer has the same configuration as that in FIG. 10.

As illustrated in the drawing, each of the first circuit patterns 30 and the second circuit patterns 32 corresponds to a half winding of the coil body. Each of the first circuit pattern 30 and the second circuit pattern 32 has a substantially C shape in plan view viewed from the interlayer direction Z, and an end point 30T of the first circuit pattern 30 and an end point 32T of the second circuit pattern 32 in plan view are directly joined without the via 24 therebetween to be electrically conducted. Thus, the first circuit pattern 30 and the second circuit pattern 32 are connected to form a spiral coil body.

Next, a method for manufacturing the coil component 100 will be described.

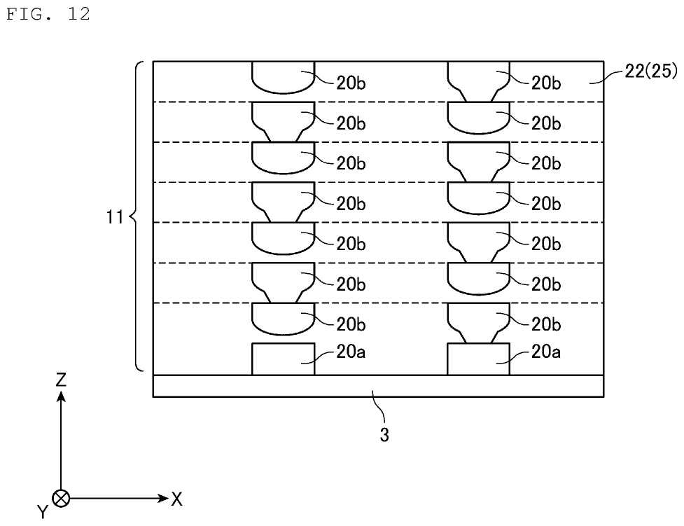

FIG. 11 is a view illustrating an example of a manufacturing process of the coil component 100.

First, the first circuit pattern 30a is embedded in the uncured insulating material 25 made of glass paste by the processing in steps Sa1 and Sa2 illustrated in FIG. 4.

Next, the surface of the uncured insulating material 25 is exposed and developed to form two second circuit pattern trenches 62 (step Sc1).

In this process, among the two second circuit pattern trenches 62, the one not connected to the lower first circuit pattern 30a is formed at a position (that is, a position at which the first circuit pattern 30a does not exist on the extension line in the interlayer direction Z) shifted in the X direction with respect to the first circuit pattern 30a, and the other one connected to the first circuit pattern 30a is formed directly above the first circuit pattern 30a.

In addition, the second circuit pattern trench 62 is formed by exposure and development such that the depth Dd is deeper than the distance De from the surface of the insulating material 25 to the first circuit pattern 30a. As a result, the second circuit pattern trench 62 formed immediately above the first circuit pattern 30a penetrates the first circuit pattern 30a. On the other hand, the second circuit pattern trench 62 formed at a position shifted in the X direction with respect to the first circuit pattern 30a is formed at a depth at which the end portion 32A enters a height range R of the first circuit pattern 20a. Similarly to the first embodiment, the second circuit pattern trench 62 also has the curved portion 62A at the bottom portion thereof.

Next, each of the two second circuit pattern trenches 62 is filled with a conductive paste by printing, and the conductive paste is dried (step Sc2). Thus, the second circuit pattern 32a is formed. Next, the first circuit pattern 30b as a third layer is printed by printing with a conductive paste, and the conductive paste is dried (step Sc3). Then, the insulating material 25 which is a photosensitive glass paste is applied so as to cover the first circuit pattern 30b exposed to the surface, and then the insulating material 25 is dried (step Sc4).

By the processing in steps Sc1 to Sc4, the first circuit pattern 30a and the second circuit pattern 32a are formed such that the end portion 32A of the second circuit pattern 32a on the lower side in the interlayer direction Z is located on the lower side in the interlayer direction Z with respect to the end portion of the first circuit pattern 30a on the upper side in the interlayer direction Z below the end portion 32A on the lower side in the interlayer direction sectional view. Then, by repeating the processing of steps Sc1 to Sc4, another first circuit pattern 30 and another second circuit pattern 32 are formed, and the laminated body 110 including a spiral coil body having a desired number of turns is manufactured.

### Other Embodiments

In the coil component 1 of the first embodiment, the laminated body 10 is configured by stacking one first circuit pattern 20a and one second circuit pattern 20b in two layers, but the configuration of the laminated body is not limited thereto. For example, as in the laminated body 11 illustrated in FIG. 12, the laminated body may be configured by stacking one first circuit pattern 20a and a plurality of (seven in the example of FIG. 12) second circuit patterns 20b in multiple layers. In this case, the first circuit pattern 20a and the plurality of second circuit patterns 20b are electrically connected in series to form a spiral coil body.

The plurality of second circuit patterns 20b as described above can be manufactured by executing step Sa5 (not illustrated) of further applying and drying the insulating material 25 that is a photosensitive glass paste so as to cover the second circuit pattern 20b exposed to the upper surface of the insulator 22 after step Sa4 illustrated in FIG. 3, and repeating the processing from step Sa3 to step Sa5.

In the laminated body 110 of the coil component 100 of the second embodiment, in the first circuit pattern 30a and the second circuit pattern 32a, and in the first circuit pattern 30c and the second circuit pattern 32c, the end portion of the second circuit pattern 32 on the lower side in the interlayer direction Z is located on the lower side in the interlayer direction Z with respect to the end portion of the first circuit pattern 30 on the upper side in the interlayer direction Z below the end portion on the lower side. However, this is an example, and the first circuit pattern 30b and the second circuit pattern 32b, and/or the first circuit pattern 30d and the second circuit pattern 32d may also be configured similarly to that described above.

In addition, in the coil components 1 and 100 in the above-described embodiments, the insulating material 25 constituting the insulator 22 may be, for example, a sintered body of ferrite or a magnetic body such as a resin containing ferrite powder. The coil components 1 and 100 are suitable for use as a power inductor mounted on a power supply circuit or the like, and for a noise filter that removes noise including an AC signal.

The present disclosure is not limited to the coil components 1 and 100, and can be applied to any other laminated electronic component. In addition, the number, positions, and the like of the first circuit pattern 20a, the second circuit pattern 20b, and the via 24 illustrated in each drawing vary according to the electronic component to which the present disclosure is applied.

Note that each of the above-described embodiments is merely an example of one aspect of the present disclosure, and can be arbitrarily modified and applied without departing from the gist of the present disclosure.

The directions such as horizontal and vertical directions, various numerical values, shapes, and materials in the above-described embodiments include a range (so-called equivalent range) in which the same functions and effects as those of the directions, numerical values, shapes, and materials are exhibited unless otherwise specified.

### Configurations Supported by Above Embodiment, Etc

The above-described embodiments, modifications, and application examples support the following configurations.

(Configuration 1) An electronic component including a first circuit pattern and a second circuit pattern stacked in this order from a lower side to an upper side in an interlayer direction; and an insulator disposed between the first circuit pattern and the second circuit pattern, in which in the second circuit pattern, an end portion on the lower side in the interlayer direction has a shape in which a width, which is a dimension perpendicular to the interlayer direction, narrows as it is positioned on the lower side in the interlayer direction in sectional view of a section including the interlayer direction.

The second circuit pattern having a shape in which the width perpendicular to the interlayer direction is narrowed in the electronic component of the configuration 1 can be formed by providing a trench for forming the second circuit pattern in the insulator using photolithography. Therefore, in the electronic component of the configuration 1, the thickness of the insulator between the second circuit pattern and the first circuit pattern is controlled to be thin, and the ratio of the first circuit pattern and the second circuit pattern, which are conductors, to the thickness in the interlayer direction can be increased.

(Configuration 2) The electronic component according to the configuration 1, in which in the second circuit pattern, the end portion on the lower side in the interlayer direction has a curved surface shape.

According to the electronic component of the configuration 2, since the insulator enters around the end portion of the second circuit pattern on the lower side, the close contact property between the second circuit pattern and the insulator can be improved.

(Configuration 3) The electronic component according to the configuration 1, in which in the second circuit pattern, the end portion on the upper side in the interlayer direction has a flat surface shape.

According to the electronic component of the configuration 3, the sectional area of the second circuit pattern can be increased to reduce the DC electric resistance of the second circuit pattern.

(Configuration 4) The electronic component according to any one of claims 1 to 3, in which in the first circuit pattern, an end portion on the lower side in the interlayer direction has a flat surface shape.

According to the electronic component of the configuration 4, the sectional area of the first circuit pattern can be increased to reduce the DC electric resistance of the first circuit pattern.

(Configuration 5) The electronic component according to any one of claims 1 to 4, further including a via that electrically connects the first circuit pattern and the second circuit pattern, in which in the via, an end portion on the lower side in the interlayer direction has a shape in which the width narrows as the end portion is positioned on the lower side in the interlayer direction in sectional view of a section including the interlayer direction.

According to the electronic component of the configuration 5, since the insulator enters the end portion of the via on the lower side, the close contact property between the via and the insulator can be improved.

(Configuration 6) The electronic component according to any one of the configurations 1 to 5, in which in sectional view of a section including the interlayer direction, the end portion of the second circuit pattern on the lower side in the interlayer direction is located on the lower side in the interlayer direction with respect to an end portion of the first circuit pattern on the upper side in the interlayer direction.

According to the electronic component of the configuration 6, the ratio of the first circuit pattern and the second circuit pattern, which are conductors, to the thickness in the interlayer direction can be further increased.

(Configuration 7) The electronic component according to any one of the configurations 1 to 6, in which the first circuit pattern and the second circuit pattern are connected to constitute a spiral coil body.

According to the electronic component of the configuration 7, the ratio of the first circuit pattern and the second circuit pattern, which are conductors, to the thickness in the interlayer direction can be increased to form a coil component having good electrical characteristics with a small DC resistance and a high inductance value.

(Configuration 8) A method for manufacturing an electronic component, the method including a first step of forming a first circuit pattern on a plane; a second step of forming a photosensitive insulating material so as to cover the first circuit pattern; a third step of forming a second circuit pattern trench by exposure and development of a surface of the insulating material; and a fourth step of filling the second circuit pattern trench with a conductive material to form a second circuit pattern, in which in the third step, the second circuit pattern trench having a bottom portion in which a width, which is a dimension perpendicular to an interlayer direction, narrows as a depth increases along the interlayer direction is formed, the interlayer direction being a direction in which the first circuit pattern and the second circuit pattern are stacked.

According to the manufacturing method of the configuration 8, since the depth of the second circuit pattern trench formed in the insulating material can be accurately controlled using photolithography, the thickness of the insulating material between the second circuit pattern and the first circuit pattern can be controlled to be thin, and the ratio of the first circuit pattern and the second circuit pattern, which are conductors, to the thickness in the interlayer direction can be increased.

(Configuration 9) The method for manufacturing an electronic component according to the configuration 8, in which in the third step, after formation of the second circuit pattern trench, a via trench is formed in a bottom portion of at least a part of the second circuit pattern trench by additional exposure and development with respect to an insulating material of the bottom portion.

According to the manufacturing method of the configuration 9, since the via trench is formed by additional exposure and development subsequent to the formation of the second circuit pattern trench, the processing step can be simplified as compared with the case where the second circuit pattern and the via are formed in separate steps.

(Configuration 10) The method for manufacturing an electronic component according to the configuration 8 or 9, in which the insulating material includes a filler material having a refractive index larger than a refractive index of a main material.

According to the manufacturing method of the configuration 10, when the second circuit pattern trench and the via trench are formed by exposure and development, a curved portion can be formed at each bottom portion.

(Configuration 11) The method for manufacturing an electronic component according to any one of the configurations 8 to 10, in which in the third step, light used for the exposure is irradiated so as to be focused on a surface of the insulating material or an inside of the insulating material with respect to the surface.

According to the manufacturing method of the configuration 11, the second circuit pattern trench or the via trench having the curved portion at the bottom portion can be formed by the focus control of the exposure light.

(Configuration 12) The method for manufacturing an electronic component according to any one of the configurations 8 to 11, in which in the third step, the second circuit pattern trench is developed in a development time shorter than a development time in which the first circuit pattern is penetrated.

According to the manufacturing method of the configuration 12, the second circuit pattern trench or the via trench having the curved portion at the bottom portion can be formed by controlling the development time after exposure.

What is claimed is:

1. An electronic component comprising:
a first circuit pattern and a second circuit pattern stacked in this order from a lower side to an upper side in an interlayer direction; and
an insulator between the first circuit pattern and the second circuit pattern,
wherein
a width of an end portion of the second circuit pattern on the lower side in the interlayer direction narrows toward the lower side in the interlayer direction in a cross-section including the interlayer direction, wherein the width of the end portion is a dimension perpendicular to the interlayer direction.

2. The electronic component according to claim 1, wherein
the end portion of the second circuit pattern on the lower side in the interlayer direction has a curved shape.

3. The electronic component according to claim 1, wherein
another end portion of the second circuit pattern on the upper side in the interlayer direction has a flat shape.

4. The electronic component according to claim 1, wherein
an end portion of the first circuit pattern on the lower side in the interlayer direction has a flat shape.

5. The electronic component according to claim 1, further comprising:
a via that electrically connects the first circuit pattern and the second circuit pattern,
wherein a width of an end portion of the via on the lower side in the interlayer direction narrows toward the lower side in the interlayer direction in a cross-section including the interlayer direction, wherein the width of the end portion of the via is a dimension perpendicular to the interlayer direction.

6. The electronic component according to claim 1, wherein
in a cross section including the interlayer direction, the end portion of the second circuit pattern on the lower side in the interlayer direction is located lower in the interlayer direction with respect to an end portion of the first circuit pattern on the upper side in the interlayer direction.

7. The electronic component according to claim 1, wherein
the first circuit pattern and the second circuit pattern are connected to configure a spiral coil.

8. The electronic component according to claim 2, wherein
the first circuit pattern and the second circuit pattern are connected to configure a spiral coil.

9. The electronic component according to claim 3, wherein
the first circuit pattern and the second circuit pattern are connected to configure a spiral coil.

10. The electronic component according to claim 4, wherein
the first circuit pattern and the second circuit pattern are connected to configure a spiral coil.

11. The electronic component according to claim 5, wherein
the first circuit pattern and the second circuit pattern are connected to configure a spiral coil.

12. The electronic component according to claim 6, wherein
the first circuit pattern and the second circuit pattern are connected to configure a spiral coil.

13. A method for manufacturing an electronic component, the method comprising:
forming a first circuit pattern on a plane;
forming a photosensitive insulating material so as to cover the first circuit pattern;
forming a second circuit pattern trench by exposing and developing a surface of the insulating material; and
filling the second circuit pattern trench with a conductive material to form a second circuit pattern,
wherein in the forming of a second circuit pattern trench, a width of the second circuit pattern trench narrows at a bottom portion thereof along an interlayer direction, wherein the interlayer direction is a direction in which the first circuit pattern and the second circuit pattern are stacked, and the width is a dimension perpendicular to the interlayer direction.

14. The method for manufacturing an electronic component according to claim 13, wherein
the second circuit pattern trench includes a plurality of the second circuit pattern trenches, and
in the forming of a second circuit pattern trench, after forming the second circuit pattern trenches, a via trench is formed in a bottom portion of at least a portion of the second circuit pattern trenches by additionally exposing and developing an insulating material in the bottom portion.

15. The method for manufacturing an electronic component according to claim 13, wherein
the insulating material comprises a main material and a filler material,
a refractive index of the filler material is larger than a refractive index of the main material.

16. The method for manufacturing an electronic component according to claim 13, wherein
in the forming of a second circuit pattern trench, light for the exposure is irradiated so as to be focused on a surface of the insulating material or an inside of the insulating material.

17. The method for manufacturing an electronic component according to claim 13, wherein
in the forming of a second circuit pattern trench, the second circuit pattern trench is developed in a development time shorter than a development time in which the insulating material covering the first circuit pattern is developed to penetrate through the insulating material to the first circuit pattern.

18. The method for manufacturing an electronic component according to claim 14, wherein
the insulating material comprises a main material and a filler material,
a refractive index of the filler material is larger than a refractive index of the main material.

19. The method for manufacturing an electronic component according to claim 14, wherein
in the forming of a second circuit pattern trench, light for the exposure is irradiated so as to be focused on a surface of the insulating material or an inside of the insulating material.

20. The method for manufacturing an electronic component according to claim 14, wherein
in the forming of a second circuit pattern trench, the second circuit pattern trench is developed in a development time shorter than a development time in which the insulating material covering the first circuit pattern is developed to penetrate through the insulating material to the first circuit pattern.
